(19) United States
(12) Patent Application Publication
(10) Pub. No.: US 2025/0112062 A1
(43) Pub. Date: Apr. 3, 2025

(54) RF POWER PATH SYMMETRY

(71) Applicant: Lam Research Corporation, Fremont, CA (US)

(72) Inventors: Miguel Benjamin Vasquez, Portland, OR (US); David Michael French, Fort Myers, FL (US)

(21) Appl. No.: 18/832,925

(22) PCT Filed: Jan. 20, 2023
(86) PCT No.: PCT/US2023/011285

§ 371 Date: Jul. 25, 2024

Related U.S. Application Data
(60) Provisional application No. 63/305,606, filed on Feb. 1, 2022.

(51) Int. Cl. H01L 21/67

(52) U.S. Cl. CPC H01L 21/67207; H01L 21/67161

(57) ABSTRACT

In some examples, a multi-station process tool comprises a plurality of process chambers, each process chamber located at a station of the multi-station process tool; and a RF power path component associated with each station of the multi-station process tool, the RF power path component geometrically positioned and oriented such that, when energized, a symmetric RF power path is created with respect to a center of the multi-station process tool.

### CLAIM OF PRIORITY

This application claims the benefit of priority to U.S. Provisional Patent Application Ser. No. 63/305,606, filed on Feb. 1, 2022, which is incorporated by reference herein in its entirety.

### FIELD

The present disclosure relates to systems and methods for RF power path symmetry and configuration, and in some examples to geometric componentry configurations for symmetric RF power path and gas flow symmetry in multi-station process modules in semiconductor manufacturing applications.

### BACKGROUND

Conventional multi-station substrate processing chambers that employ powered pedestals typically use a variety of component configurations to provide RF power. A conventional RF power path configuration is typically constrained by what components can fit next to or within external chamber hardware. The geometric configuration of RF power components can sometimes be variable with excessive or unacceptable tolerance levels and/or be unsymmetrical with respect to a substrate processing station.

External chamber hardware can include process gas exhaust lines, valving componentry, and a number of filters and enclosures for RF matching circuits, and so forth. Conventional configurations of exhaust lines, for example, can make access to lower chamber hardware difficult. The lower portions of some process stations are crowded which can make adding or configuring new hardware and RF power componentry difficult. In particular, some lower chamber hardware is especially difficult to work on because of a pedestal lift orientation which is dictated by the gas line geometry and location. Conventional configurations of external chamber hardware can significantly impede the creation of common geometric outlays of RF power componentry and the establishment of symmetrical RF power paths.

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

In some examples, a multi-station process tool comprises a plurality of process chambers, each process chamber located at a station of the multi-station process tool; and a RF power path component associated with each station of the multi-station process tool, the RF power path component geometrically positioned and oriented such that, when energized, a symmetric RF power path is created with respect to a symmetry axis of the multi-station process tool.

In some examples, the symmetry axis is located at a center of the multi-station process tool. In some examples, the center of the multi-station process tool is defined by an axis of a spindle motor of the multi-station process tool.

In some examples, the RF power path component includes an RF component enclosure.

In some examples, the multi-station process tool of claim 1 includes a quad station process module (QSM) having a four stations, each station including a process chamber.

In some examples, a geometric position and orientation of a first RF power path component in relation to a first station of the four stations of the QSM, is symmetrical with a geometric position and orientation of a second RF power path component in relation to a second station of the four stations of the QSM.

In some examples, the geometric position and orientation of a first non-RF component in relation to the first station, is symmetrical with the geometric position and orientation of a second non-RF component in relation to the second station of the QSM.

In some examples, an asymmetry of the RF power path component or non-RF component is common to each station of the multi-station process tool.

In some examples, the multi-station process tool further comprises a foreline assembly including four inlets each connectable to a chamber port of a station of the QSM; an outlet connectable directly or indirectly to a vacuum source; a first foreline bifurcation disposed proximate an outlet of the foreline assembly; two second foreline bifurcations, each disposed between the first foreline bifurcation and a respective pair of the four inlets; and the first and second foreline bifurcations dividing the foreline assembly into three sections, a first section extending from the four inlets to the two second foreline bifurcations, a second section extending from the two second foreline bifurcations to the first foreline bifurcation, and a third section extending from the first bifurcation to the outlet of the foreline assembly.

In some examples, a respective diameter of a foreline in each section increases stepwise at a respective bifurcation in a direction of gas flow from at least one of the four inlets to the outlet of the foreline assembly; and is constant within a respective section of the foreline assembly.

In some examples, a diameter of a foreline in the first section is in a range 38.1 mm (approximately 1.5 inches) to 63.5 mm (approximately 2.5 inches), a diameter of a foreline in the second section is in the range 63.5 mm (approximately 2.5 inches) to 88.9 mm (approximately 3.5 inches), and a diameter of a foreline in the third section is in the range 88.9 mm (approximately 3.5 inches) to 114.3 mm (approximately 4.5 inches).

In some examples, the diameter of the foreline in the first section is 50.8 mm (approximately 2 inches), the diameter of the foreline in the second section is 76.2 mm (approximately 3 inches), and the diameter of the foreline in the third section is 101.6 mm (approximately 4 inches).

In some examples, the multi-station process tool further comprises a T-piece connector provided at each of the two second bifurcations.

In some examples, the T-piece connector includes outwardly converging conical sections that transition the diameter of a foreline in the first section to the diameter of a foreline in the second section.

In some examples, a separation distance between the T-piece connector and an underside of the QSM is configured to accommodate an RF power path component between the T-piece connector and underside of the QSM.

### BRIEF DESCRIPTION OF THE DRAWINGS

Some embodiments are illustrated by way of example and not limitation in the views of the accompanying drawing:

FIGS. 1-4 show schematic views of substrate processing tools in which example RF power path and gas flow symmetries of the present disclosure may be deployed.

FIG. 5 is a schematic view of an example substrate processing tool including a quad station process module in which example RF power path and gas flow symmetries of the present disclosure may be deployed.

FIGS. 6-8 show example configurations of RF power path components and a foreline assembly fitted to a QSM, according to example embodiments.

FIGS. 9-10 show pictorial views of a foreline assembly (for clarity not fitted to a QSM), according to example embodiments.

FIG. 11 shows a pictorial view of a spool piece, according to an example embodiment.

FIG. 12 is a flow chart showing operations in a method, according to an example embodiment.

FIG. 13 shows aspects of a semiconductor manufacturing process, according to an example.

### DESCRIPTION

The description that follows includes systems, methods, techniques, instruction sequences, and computing machine program products that embody illustrative embodiments of the present disclosure. In the following description, for purposes of explanation, numerous specific details are set forth in order to provide a thorough understanding of example embodiments. It will be evident, however, to one skilled in the art that the present disclosure may be practiced without these specific details.

A portion of the disclosure of this patent document may contain material that is subject to copyright protection. The copyright owner has no objection to the facsimile reproduction by anyone of the patent document or the patent disclosure, as it appears in the Patent and Trademark Office patent files or records, but otherwise reserves all copyright rights whatsoever. The following notice applies to any data as described below and in the drawings that form a part of this document: Copyright Lam Research Corporation, 2019-2021, All Rights Reserved.

A substrate processing system may be used to perform deposition, etching and/or other treatment of substrates such as semiconductor wafers. During processing, a substrate is arranged on a substrate support in a processing chamber of the substrate processing system. During etching or deposition, gas mixtures including one or more etch gases or gas precursors, respectively, are introduced into the processing chamber and plasma may be struck using RF power to activate chemical reactions.

The substrate processing system may include a plurality of substrate processing tools arranged within a fabrication room. Each of the substrate processing tools may include a plurality of process modules. Typically, a substrate processing tool includes up to six process modules.

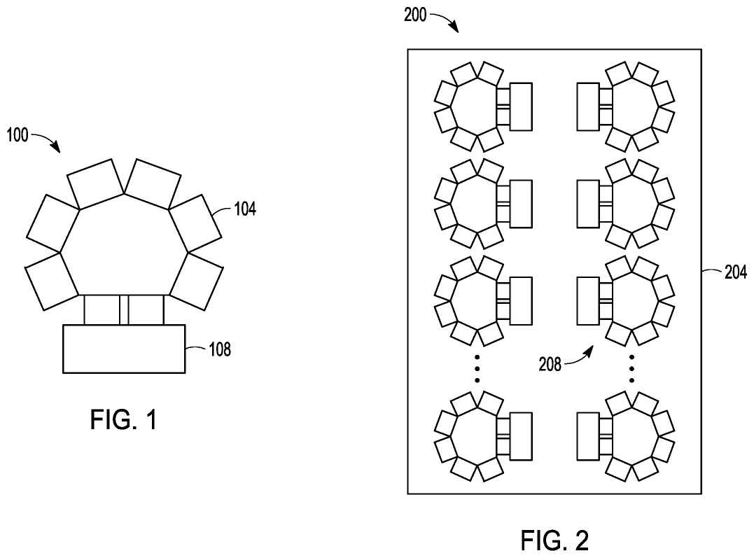

Referring now to FIG. 1, a top-down view of an example substrate processing tool 100 is shown. The substrate processing tool 100 includes a plurality of process modules 104. In some examples, each of the process modules 104 may be configured to perform one or more respective processes on a substrate. Substrates to be processed are loaded into the substrate processing tool 100 via ports of a loading station of an equipment front end module (EFEM) 108 and then transferred into one or more of the process modules 104. For example, a substrate may be loaded into each of the process modules 104 in succession. A process module 104 may be or include a multi-station process module, such as a quad station process module (QSM) described further below. Referring now to FIG. 2, an example arrangement 200 of a fabrication room 204 including a plurality of substrate processing tools 208 is shown.

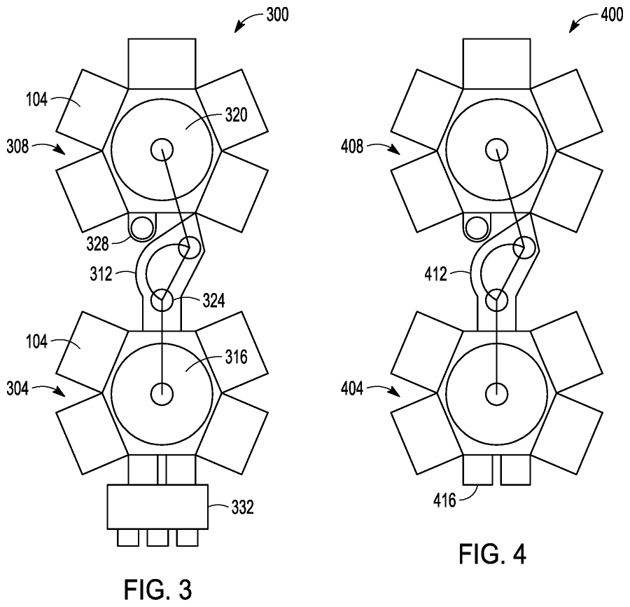

FIG. 3 shows a first example configuration 300 including a first substrate processing tool 304 and a second substrate processing tool 308. The processing tools 304 and 308 may each include one or more processing modules 104, or QSMs. The first substrate processing tool 304 and the second substrate processing tool 308 are arranged sequentially and are connected by a transfer stage 312, which is under vacuum. As shown, the transfer stage 312 includes a pivoting transfer mechanism configured to transfer substrates between a vacuum transfer module (VTM) 316 of the first substrate processing tool 304 and a vacuum transfer module (VTM) 320 of the second substrate processing tool 308. However, in other examples, the transfer stage 312 may include other suitable transfer mechanisms, such as a linear transfer mechanism. In some examples, a first robot (not shown) of the VTM 316 may place a substrate on a support 324 arranged in a first position, the support 324 is pivoted to a second position, and a second robot (not shown) of the VTM 320 retrieves the substrate from the support 324 in the second position. In some examples, the second substrate processing tool 308 may include a storage buffer 328 configured to store one or more substrates between processing stages.

The transfer mechanism may also be stacked to provide two or more transfer systems between the substrate processing tools 308 and 304. Transfer stage 312 may also have multiple slots to transport or buffer multiple substrates at one time.

In the configuration 300, the first substrate processing tool 304 and the second substrate processing tool 308 are configured to share a single equipment front end module (EFEM) 332.

FIG. 4 shows a second example configuration 400 including a first substrate processing tool 404 and a second substrate processing tool 408 arranged sequentially and connected by a transfer stage 412. The configuration 400 is similar to the configuration 300 of FIG. 3 except that in the configuration 400, the EFEM 332 is eliminated. Accordingly, substrates may be loaded into the first substrate processing tool 404 directly via airlock loading stations 416 (e.g., using a storage or transport carrier such as a vacuum wafer carrier, front opening unified pod (FOUP), an atmospheric (ATM) robot, etc., or other suitable mechanisms).

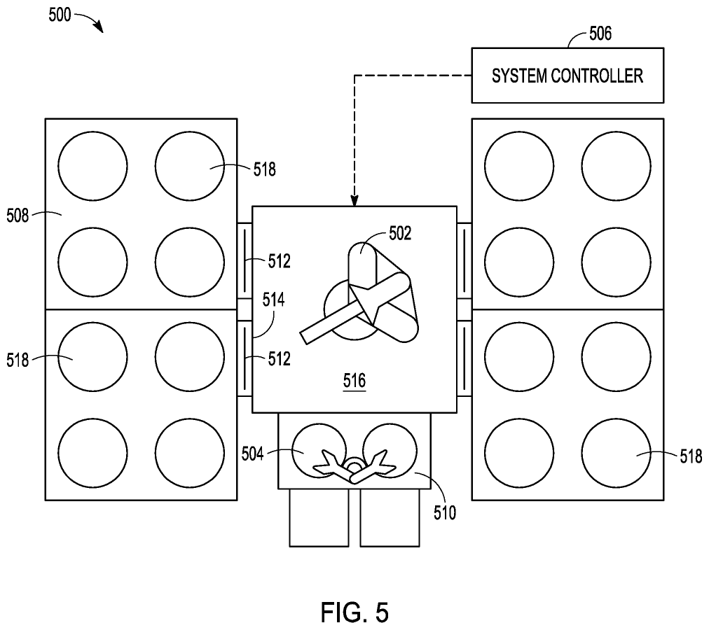

Examples of the present disclosure may be deployed in a multi-station process module or process chamber, such as a QSM. In some examples, as shown in FIG. 5, a substrate processing tool 500 includes four QSMs 508 disposed at respective corners of the substrate processing tool 500. Other arrangements of the process modules 508 are possible. Each QSM 508 has four stations 518. The substrate processing tool 500 includes transfer robots 502 and 504, referred to collectively as transfer robots 502/504. The processing tool 500 is shown without mechanical indexers for example purposes. In other examples, the respective process modules 508 of the tool 500 may include mechanical indexers.

A VTM 516 and an EFEM 510 may each include one of the transfer robots 502/504. The transfer robots 502/504 may have the same or different configurations. In some examples, the transfer robot 502 is shown having two arms, each having two vertically stacked end effectors. The robot 502 of the VTM 516 selectively transfers substrates to and from the EFEM 510 and between the process modules 508. The robot 504 of the EFEM 510 transfers substrates into and out of the EFEM 510. In some examples, the robot 504 may have two arms, each arm having a single end effector or two vertically stacked end effectors. A system controller 506 may control various operations of the illustrated substrate processing tool 500 and its components including, but not limited to, operation of the robots 502/504, and rotation of the respective indexers of the process modules 508, and so forth.

The tool 500 is configured to interface with, for example, each of the four QSMs 508. Each QSM 508 may have a single load station accessible via a respective slot 512. Other arrangements are possible. In the illustrated manner, two of the QSMs 508, each having a single load station, is coupled to a side 514 of the VTM 516. The EFEM 510 may be arranged at least partially between two of the process modules 508.

During substrate processing in a QSM 508, processing gases enter the module to assist in creating a plasma, for example. The gases then exit the process module 508. The expulsion of exhaust gases may be performed by a vacuum or exhaust line, also referred to as a foreline or foreline assembly in this specification. One of more forelines in a foreline assembly may be situated underneath each QSM 508 in the processing tool 500 and be connected to a vacuum source to expel gases from the QSM 508. Each foreline of a foreline assembly may serve to vent gasses from a respective station 518 in a QSM 508.

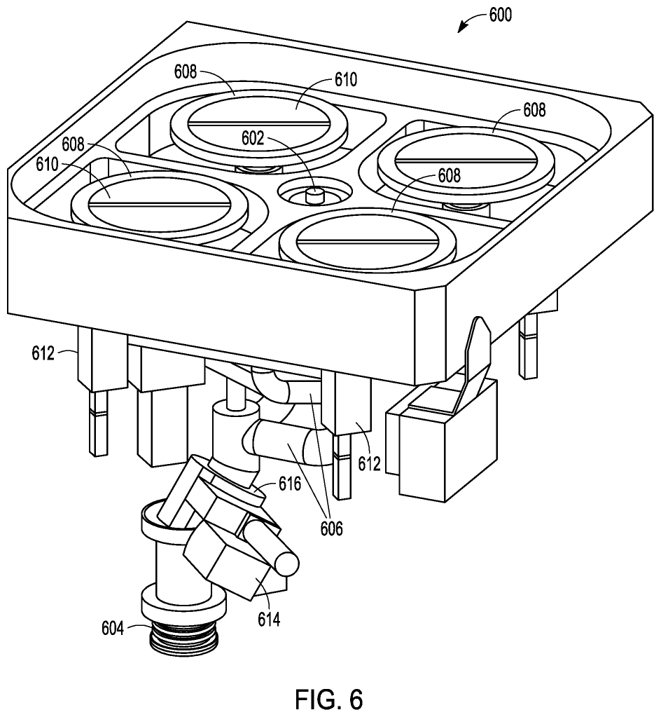

FIG. 6 generally shows an example configuration of a QSM 600. Some QSM 600 parts are omitted for clarity. The QSM 600 includes four stations 608 disposed in a generally square configuration at respective corners of the QSM 600. Other arrangements of the stations 608 are possible. Each station includes a vacuum chamber for processing a substrate using RF power and plasma gas flows as described more fully below. Each station 608 in the QSM 600 includes a wafer support 610 which supports a substrate (also generally referred to without limitation as a wafer herein) during processing. In some examples, the wafer support 610 includes a powered pedestal or an electrostatic chuck (ESC) in an RF power path. Other types of wafer support or components may be used to support wafers in a station 608 to perform different types of processes on them.

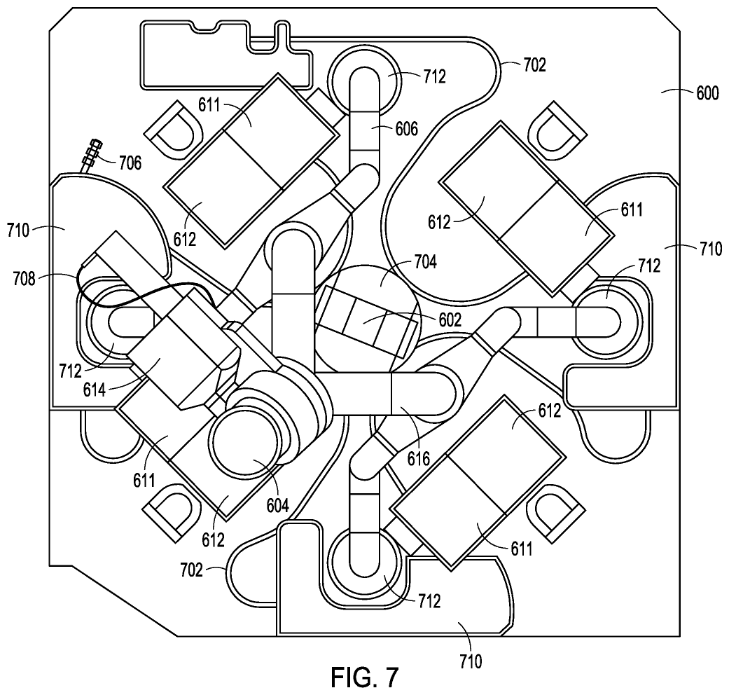

Each station 608 includes a respective lift pin actuator assembly 612 which can move lift pins upward and unseat a wafer during wafer transfer. The QSM 600 includes a spindle 602 that can transfer wafers from one wafer support 610 to another. The spindle 602 may be driven by a spindle motor 704 visible more clearly in FIG. 7. For clarity, a transfer plate on which the spindle 602 can act is not pictured in the view. The transfer plate may be rotated during a wafer transfer phase and the movement of a wafer during this phase may be coordinated with wafer movements imparted by other wafer transfer mechanisms, for example the transfer robots 502/504 of FIG. 5.

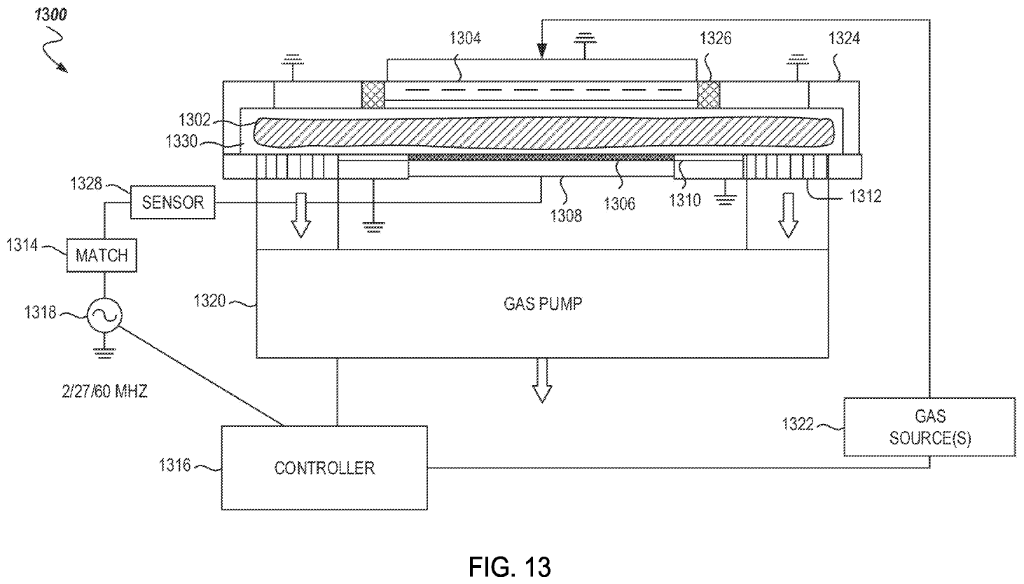

For illustrative purposes, FIG. 13 shows aspects of an example semiconductor manufacturing process that may occur at a station 608 in a processing tool such as a QSM 600. FIG. 13 illustrates a vacuum chamber 1300. The vacuum chamber may be an etching or deposition chamber for manufacturing substrates, according to some examples. Exciting an electric field between two electrodes in an RF power path is one of the methods to obtain radio frequency (RF) gas discharge in a vacuum chamber. When an oscillating voltage is applied between the electrodes, the discharge obtained is referred to as a CCP discharge.

Plasma 1302 may be created within a processing zone 1330 of the vacuum chamber 1300 utilizing one or more process gases to obtain a wide variety of chemically reactive by-products created by the dissociation of the various molecules caused by electron-neutral collisions. The chemical aspect of etching involves the reaction of the neutral gas molecules and their dissociated by-products with the molecules of the to-be-etched surface and producing volatile molecules, which may be pumped away. When a plasma is created, the positive ions are accelerated from the plasma across a space-charge sheath separating the plasma from chamber walls to strike the substrate surface with enough energy to remove material from the substrate surface. The process of using highly energetic and chemically reactive ions to selectively and anisotropically remove materials from a substrate surface is called reactive ion etch (RIE). In some examples, the vacuum chamber 1300 may be used in connection with PECVD or PEALD deposition processes.

A controller 1316 manages the operation of the vacuum chamber 1300 by controlling the different elements in the chamber, such as RF generator 1318, gas sources 1322, and gas pump 1320. In one embodiment, fluorocarbon gases, such as CF₄ and C₄F₈, are used in a dielectric etch process for their anisotropic and selective etching capabilities, but the principles described herein may be applied to other plasma-creating gases. The fluorocarbon gases are readily dissociated into chemically reactive by-products that include smaller molecular and atomic radicals. These chemically reactive by-products etch away the dielectric material.

The vacuum chamber 1300 illustrates a processing chamber with an upper (or top) electrode 1304 and a lower (or bottom) electrode 1308 in an RF power path. The upper electrode 1304 may be grounded or coupled to an RF generator (not shown), and the lower electrode 1308 is coupled to the RF generator 1318 via a matching network 1314. The RF generator 1318 provides an RF signal between the upper electrode 1304 and the lower electrode 1308 to generate RF power in one or multiple (e.g., two or three) different RF frequencies. According to a desired configuration of the vacuum chamber 1300 for a particular operation, at least one of the multiple RF frequencies may be turned ON or OFF. In the embodiment shown in FIG. 13, the RF generator 1318 is configured to provide at least three different frequencies, e.g., 400 kHz, 2 MHz, 27 MHz, and 60 MHz, but other frequencies are also possible.

The vacuum chamber 1300 includes a gas showerhead on the top electrode 1304 to input process gas into the vacuum chamber 1300 provided by the gas source(s) 1322, and a perforated confinement ring 1312 that allows the gas to be pumped out of the vacuum chamber 1300 through a foreline of a foreline assembly (for example) by a gas pump 1320. In some example embodiments, the gas pump 1320 is a turbomolecular pump, but other types of gas pumps may be utilized.

When substrate 1306 is present in the vacuum chamber 1300, silicon focus ring 1310 is situated next to substrate 1306 such that there is a uniform RF field at the bottom surface of the plasma 1302 for uniform etching (or deposition) on the surface of the substrate 1306. The embodiment of FIG. 13 shows a triode reactor configuration where the top electrode 1304 is surrounded by a symmetric RF ground electrode 1324. Insulator 1326 is a dielectric that isolates the ground electrode 1324 from the top electrode 1304. Other implementations of the vacuum chamber 1300, including ICP-based implementations, are also possible without changing the scope of the disclosed examples.

As used herein, the term “substrate” indicates a support material upon which, or within which, elements of a semiconductor device are fabricated or attached. A substrate (e.g., substrate 106) may include, for example, wafers (e.g., having a diameter of 100 mm, 150 mm, 200 mm, 300 mm, 450 mm, or larger) composed of, for example, elemental-semiconductor materials (e.g., silicon (Si) or germanium (Ge)) or compound-semiconductor materials (e.g., silicon germanium (SiGe) or gallium arsenide (GaAs)). Additionally, other substrates include, for example, dielectric materials such as quartz or sapphire (onto which semiconductor materials may be applied). Example substrates include blanket substrates and patterned substrates. A blanket substrate is a substrate that includes a low-surface (or planar) top surface. A patterned substrate is a substrate that includes a high-surface (or structured) top surface. A structured top surface of a substrate may include different high-surface-area structures such as 3D NAND memory holes or other structures.

Each frequency generated by the RF generator 1318 may be selected for a specific purpose in the substrate manufacturing process. In the example of FIG. 13, with RF powers provided at 400 kHz, 2 MHz, 27 MHz, and 60 MHz, the 400 kHz or 2 MHz RF power provides ion energy control, and the 27 MHz and 60 MHz powers provide control of the plasma density and the dissociation patterns of the chemistry. This configuration, where each RF power may be turned ON or OFF, enables certain processes that use ultra-low ion energy on the substrates, and certain processes (e.g., soft etch for low-k materials) where the ion energy has to be low (e.g., under 700 or 200 eV).

In another embodiment, a 60 MHz RF power is used on the upper electrode 1304 to get ultra-low energies and very high density. This configuration allows chamber cleaning with high-density plasma when substrate 106 is not in the vacuum chamber 1300 while minimizing sputtering on the electrostatic chuck (ESC) surface. The ESC surface is exposed when substrate X06 is not present, and any ion energy on the surface should be avoided, which is why the bottom 2 MHz and 27 MHz power supplies may be off during cleaning.

In an example embodiment, the vacuum chamber 1300 further includes a sensor 1328 which may be placed between the matching network 1314 of the RF generator 1318 and the lower electrode 1308. The sensor 1328 may include a voltage-current (or V-I) sensor configured to generate a plurality of signals (e.g., sensed data) that are indicative of at least one signal characteristic of RF signals generated by the RF generator 1318 at a corresponding plurality of time instances. For example, the V-I sensor may generate a plurality of signals that are indicative of one or more of the following signal characteristics of RF signals: voltage, current, phase, delivered power, and impedance. In some aspects, the plurality of signals generated by the sensor 1328 at the corresponding plurality of time instances may be stored (e.g., in on-chip memory of controller 1316 or the sensor 1328) and later retrieved (e.g., by the controller 1316) for subsequent processing. In other aspects, the plurality of signals generated by the sensor 1328 at the corresponding plurality of time instances may be automatically communicated to the controller 1316 as they are generated.

As discussed above, conventional configurations of external chamber hardware can significantly impede the creation of common geometric outlays of RF power componentry and the establishment of symmetrical RF power paths. To that end, examples of the present disclosure are directed to providing geometric componentry configurations for symmetric RF power path and gas flow symmetry, especially in multi-station process modules in semiconductor manufacturing applications. RF power path symmetry, or commonality, can be important for uniformity of wafer processing in multi-station processing tools, such as a QSM as described herein.

In some examples, providing RF power path symmetry across stations of a QSM for example may not necessarily mean providing “true” symmetry for (or within) each station, but simply that any asymmetry in a given RF power path is commonly distributed or shared by each station i.e., is common to each station. In these examples, the RF power path may be said to be symmetric in the sense that each station is commonly asymmetric.

An asymmetry that is not commonly shared across stations, or even an asymmetry in RF power path generally, can be very disruptive in substrate manufacturing processes. RF frequencies in excess of 27 MHz, for example 40 MHz, 60 MHz, or even 100 MHz, have a wavelength which is not considered long compared to the hardware or system size. A given physical asymmetry between stations in the geometric location of an RF power generator is “relatively” much higher at such small wavelengths as compared to the wavelengths associated with lower RF power, for example. In current processes that employ very high frequencies, the ability to create an asymmetric RF power path becomes increasingly likely. Moreover, at such high frequencies, non-linear circuit elements to include the plasma, for example, can lead to harmonic frequency generation and the prevalence of harmonics at multiples of the fundamental frequency make the challenge to create symmetry even more difficult.

Some examples seek to provide a symmetric RF power path with respect to a chamber or tool center, for example the spindle 602 at the center of the QSM 600 described above. In such examples, the spindle 602 serves as an axis of symmetry. Optimizing or improving an RF power path symmetry (or common asymmetry) can increase the ability to establish station to station matching for RF power and film properties. The symmetric geometric placement and configuration of RF power path componentry, as described herein, seek to make this possible.

Some examples herein are directed to establishing gas flow symmetry in a multi-station processing module. Some examples include a foreline assembly configured to enable gas flow symmetry across stations. Some example configurations of chamber components combine aspects of RF power path symmetry and gas flow symmetry. Example components may include a foreline, a foreline assembly, a valve or valving component, or an RF power path component such as an RF filter or RF component enclosure. Example component configurations enabling a RF power path symmetry, a gas flow symmetry, and/or a combined RF power path and gas flow symmetry may include one or more symmetric geometric configurations of components. The symmetric configuration of components may include components common to each station of a multi-station processing module.

With reference again to FIG. 6, a section of a foreline assembly 606 is visible below the QSM 600. This section is called a “third section” of the foreline assembly and is described in more detail below. The foreline assembly 606 includes a lower outlet 616 connectable directly or indirectly to a vacuum source 604 and other downstream components such a combination or control valve 614. During wafer processing, the foreline assembly 606 evacuates exhaust gases from each of the stations 608 (process chambers) and the QSM as a whole during wafer or substrate processing.

FIG. 7 is a schematic view of an underside and related components of the QSM 600. Underside views of the foreline assembly 606 and the lift pin actuator assemblies 612 may be seen. An RF component enclosure 611 is attached to each lift pin actuator assembly 612. As described in more detail below, each (upper) inlet 712 of the foreline assembly 606 is connected to a respective station (processing chamber) 608 at a respective chamber port.

It may be noted that the illustrated configuration of the foreline assembly 606 allows room for the orientation of the lift pin actuator assemblies 612 relative to the axis of the spindle 602 (or spindle motor 704) to remain the same i.e., they follow an imaginary concentric ring around the spindle 602 in the same direction. The (lower) outlet 616 of the foreline assembly 606 is connectable directly or indirectly to a vacuum source 604 and the control valve 614. The QSM 600 may include various components and supply lines 702, connectors 706, control wiring 708, and other modules 710 to supply the QSM 600, as shown. Other componentry and QSM arrangements are possible.

It will be noted that the geometric position and orientation of each RF component enclosure 611, within its own QSM quadrant or in relation to its own station 608, is symmetrical to the geometric position and orientation of another RF component enclosure within its own respective quadrant or station 608. In other words, each quadrant is may be said to be “clocked” around 90 degrees with respect to an adjacent quadrant, but in all other respects the geometric positions and orientations of the respective RF component enclosures within each quadrant are the same. In this sense, the geometric outlays of the RF component enclosures may be said to be symmetrical. The 90 degree “clocking” of the quadrants occurs around the axis of the spindle 602 or spindle motor 704 which represents an axis of symmetry accordingly.

The symmetrical outlay of RF componentry may be applied to other components in an RF power path disposed externally or underneath a QSM 600. For example, component such as RF power generators or filters. Some examples apply geometric symmetry to non-RF componentry. For example, it will be noted that the geometric position and orientation of each lift pin actuator assembly 612, within its own QSM quadrant or in relation to its own station 608, is symmetrical to the geometric position and orientation of another lift pin actuator assembly within its own respective quadrant or station 608.

In some examples, each quadrant of the QSM may have a local “asymmetry” and yet the QSM remain “symmetrical” overall in that the local asymmetry is rendered common to each quadrant or station. For example, let us assume a mounting bracket for a RF component enclosure 611 is manufactured with an error or design fault that causes a component within the enclosure 611 to be misaligned slightly. Let us assume the misalignment ordinarily would cause an unhelpful disturbance in an RF flux applied to the QSM 600 and perhaps even lead to manufacturing errors. In being commonly positioned and oriented, however, the error in each RF component enclosure 611 is equally distributed, as it were, and is rendered common to each quadrant. If needed, a single process accommodation can be made for this error, even though the defect occurs in four places. In this sense a QSM “symmetry” is created which, in some examples, enables consistency in manufacturing processes and conditions across each of the different QSM stations 608 even though a given component of the QSM may have a local defect, or misalignment. Aspects such as predictability, uniformity of output, and consistency of process can be key issues in semiconductor manufacturing, especially when operating at the high frequencies discussed above.

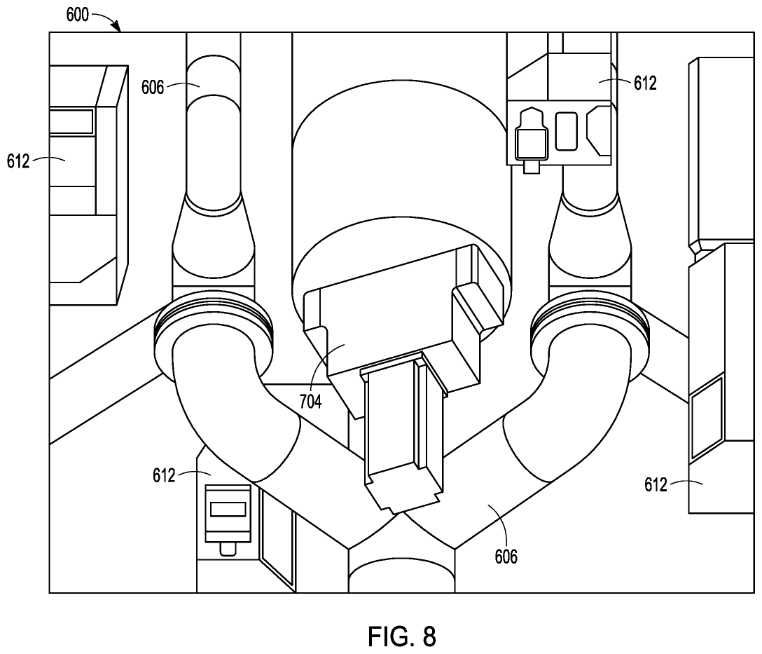

In some examples, the ability to derive this functionality and RF power path symmetry is made possible by the geometric configuration of a foreline assembly 606. In some examples, the geometric configuration is open and symmetrical. For example, FIG. 8 shows a further pictorial view of an example foreline assembly 606 fitted to the underside of a QSM 600. The foreline assembly 606, the spindle motor 704, and the lift pin actuator assemblies 612 are again visible in the view. It may be noted that the illustrated configuration of the foreline assembly 606 allows considerable clearance around the spindle motor 704 and other process support components positioned underneath the QSM 600. This clearance enables the design and symmetric placement of RF and other components as discussed above. For example, the consistent and symmetric orientation of the lift pin actuator assemblies 612 for example enables replacement part uniformity and ease of access to the QSM 600 for operators during maintenance of the QSM 600 or between wafer processing cycles.

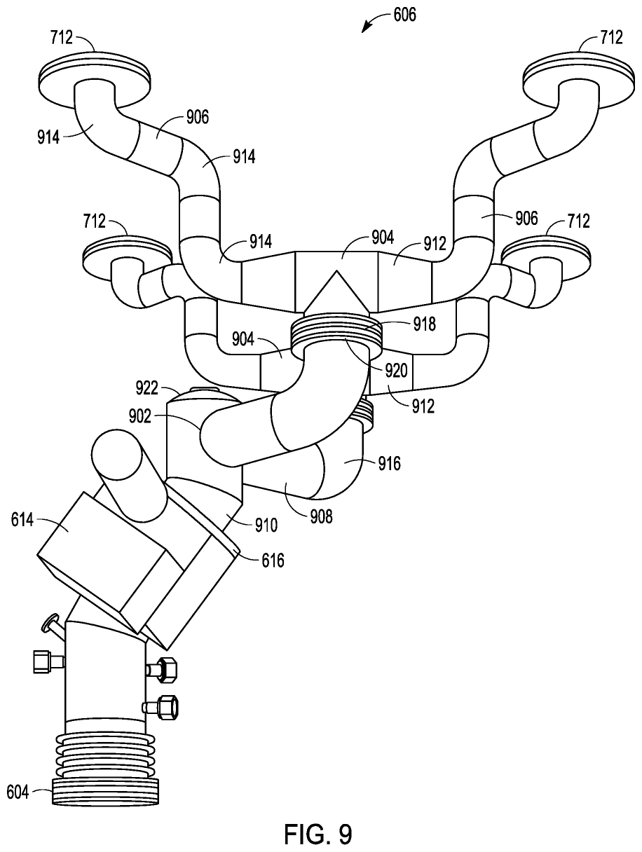

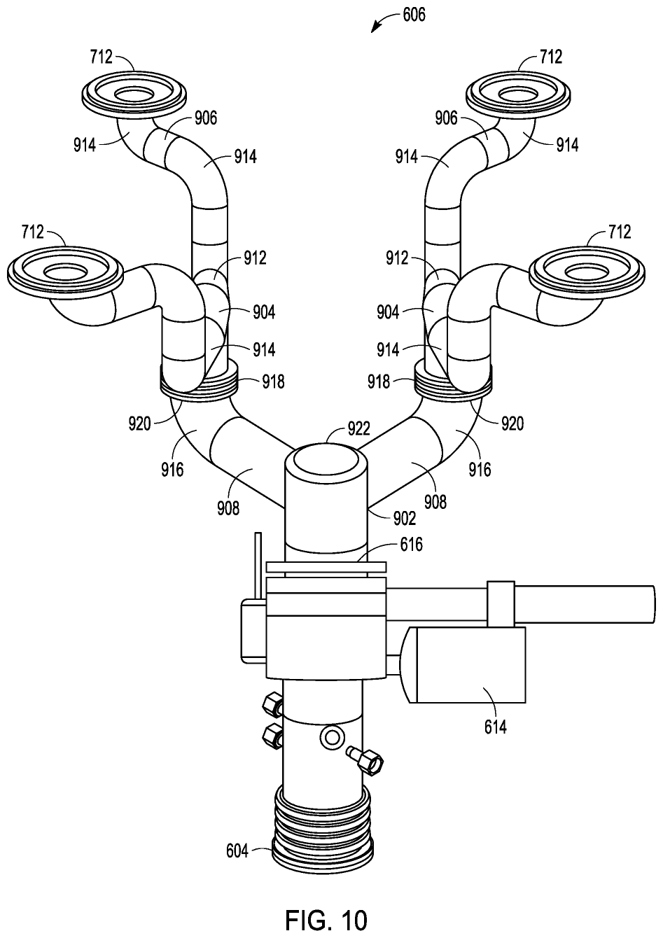

FIGS. 9-10 show pictorial views of a foreline assembly 606 not fitted to a QSM. The illustrated foreline assembly 606 includes four inlets that include, in this example, chamber ports 712. Other inlet numbers or configurations are possible depending on process requirements. For example, a 2-inch inlet 712 may include a 4-inch chamber port to facilitate unmodified fitting of a foreline assembly 606 to the existing ports in an in-situ process module (chamber) 608. An outlet 616 of the foreline assembly 606 is connectable directly or indirectly to a vacuum source at 604. A vacuum pressure and exhaust gas flow though the foreline assembly 606 can be regulated by a control valve, such as a combination control valve 614.

In some examples, the forelines in a foreline assembly 606 include three bifurcations. For example, a first or main bifurcation 902 is provided proximate the outlet 616. At the first bifurcation 902, a relatively large diameter pipe section joins two relatively smaller pipe sections 908, as illustrated in the example of FIG. 9. The respective diameters of the two (now bifurcated) forelines 908 nearer the process modules 608 may be approximately the same, as shown in the view for example. In some examples, the respective pipe diameters may be different depending on processing flow or pressure requirements. The first bifurcation 902 may include a plenum chamber 922 to equalize vacuum pressure for more even distribution into the bifurcated forelines 908. From the alternate perspective of the direction of exhaust gas flow outwardly down from the process modules 908, the two forelines 908 upstream of the first bifurcation 902 merge into one line and the exhaust gases form one gas stream.

Two second bifurcations 904 of the foreline assembly are disposed between the first bifurcation 902 and respective pairs of the inlets 712, as shown. Only one of the two second bifurcations 904 is fully visible in the view of FIG. 9. In some examples, the first and second bifurcations 902 and 904 divide the forelines of the foreline assembly 606 into sections: a first section 906 extending from the inlets 712 to the two second bifurcations 904, a second section 908 extending from the second bifurcations 904 to the first bifurcation 902, and a third section 910 extending from the first bifurcation 902 to the outlet 616 of the foreline assembly 606.

A diameter of a foreline in the first section 906 may be in the range 38.1 mm (approximately 1.5 inches) to 63.5 mm (approximately 2.5 inches). A diameter of a foreline in the second section 908 may be in the range 63.5 mm (approximately 2.5 inches) to 88.9 mm (approximately 3.5 inches). A diameter of a foreline in the third section 910 may be in the range 88.9 mm (approximately 3.5 inches) to 114.3 mm (approximately 4.5 inches). In the illustrated example, a 2-3-4 foreline assembly 606 is shown, denoting the use of a 2-inch line in the first section 906, a 3-inch line in the second section 908, and a 4-inch line in the third section 910 of the foreline assembly 606. Other line configurations are possible. In some examples, the diameter of each line in each section 906, 908 and 910 between an inlet 712 or a connector is substantially uniform throughout.

In some examples, a T-piece connector 912 is provided at each second bifurcation 904. An example T-piece connector 912 may include two outwardly converging conical sections, as shown, that transition the diameter of the 3-inch foreline to the 2-inch foreline (or vice versa in the direction of exhaust gas flow). In some examples, a position of or a separation distance between the T-piece connector 912 and an underside of a QSM 600 may be selected to accommodate other components, for example a lift pin actuator assembly 612, an RF component enclosure 611, a spindle motor 704, an mDSC motor, or an eDSC motor.

In the first section 906, the foreline assembly 606 includes four forelines that each include three substantially right-angled elbows 914 disposed at intervals along the forelines. The elbows are provided between each inlet 712 and a respective second bifurcation 904. In some examples, the forelines in the first section 906 are generally continuous and no separable joints or unions are provided. Other arrangements are possible.

In the second section 908, the foreline assembly 606 includes two forelines that each include one substantially right-angled elbow 916 disposed between the first 902 and second 904 bifurcations. In some examples, a separable union 918 is provided at or towards an upper end of each elbow 916. Each union 918 may include, as shown, two opposed flanges 920 that can be bolted together to join each elbow 916 to an exit port of the T-piece connector 912. The flanges 920 lie in horizontal planes and their positioning above an elbow 916 creates a symmetry for both halves of the second section 908 in the sense that different “right-handed” or “left-handed” elements in the second section 908 are avoided. The horizontal orientation of the flanges 920 also allow an operator ease of access to nuts or bolts passing vertically through the flanges 920 to secure the union 918 since the nuts or bolts can be accessed from directly underneath the QSM 600, as opposed to requiring a lateral space in order to do so. This horizontal orientation of the union 918 and flanges 920, together with the aforementioned improved clearance around the spindle motor 704, further assist ease of operator maintenance of a QSM 600.

The third section 910 of the foreline assembly 606 may include the plenum chamber 922 referenced above and a relatively short length of large diameter foreline extending from the plenum chamber 922 to the outlet 616 of the foreline assembly 606.

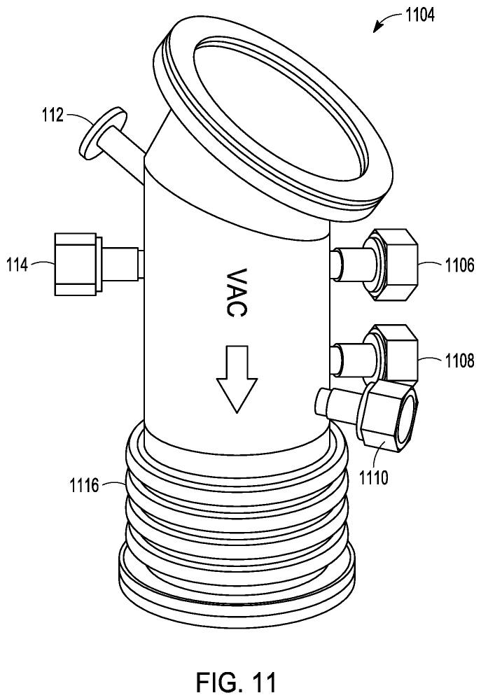

With reference to FIG. 11, in some examples a foreline assembly 606 includes or is connectable to a spool piece 1104. The spool piece 1104 may be interposed between a vacuum source 604 and the outlet 616 of the foreline assembly 606. For convenience, an example spool piece 1104 may include an indicator 1102 pointing to a direction of the vacuum source 604. In some examples, a spool piece 1104 includes a slow-pump inlet 1106, a TEOS divert 1108, and a gas box divert 1110. In some examples, a spool piece 1104 includes a precursor or other divert 1112, a Hastings gauge port 1114, and a bellows 1116 to facilitate operator serviceability and ease of adjustment of the spool piece 1104.

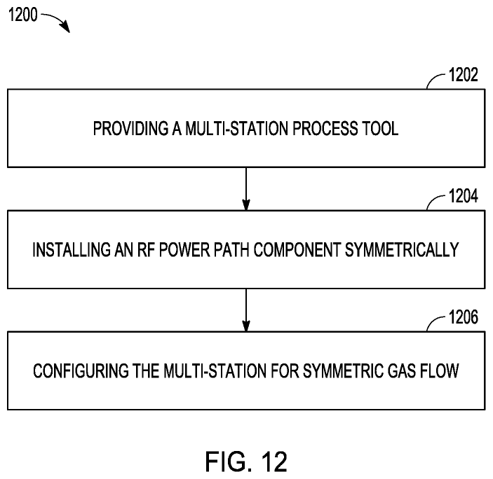

Some embodiments include methods. With reference to FIG. 12, an example method 1200 of providing a symmetric RF power path at a multi-station process tool comprises: at operation 1202, providing a multi-station process tool including a plurality of process chambers, each process chamber located at a station of the multi-station process tool; and, at operation 1204, installing a RF power path component in association with each station of the multi-station process tool, the RF power path component being geometrically positioned and oriented such that, when energized, a symmetric RF power path is created with respect to a symmetry axis of the multi-station process tool.

In some examples, the symmetry axis is located at a center of the multi-station process tool. In some examples, the center of the multi-station process tool is defined by an axis of a spindle motor of the multi-station process tool.

In some examples, the RF power path component includes an RF component enclosure.

In some examples, the multi-station process tool includes a quad station process module (QSM).

In some examples, the method 1200 further comprises, at operation 1206, configuring the QSM for a symmetric gas flow, the configuring of the QSM comprising, at least: fitting a foreline assembly to the QSM, the foreline assembly including: four inlets each connectable to a chamber port of a station of the QSM; an outlet connectable directly or indirectly to a vacuum source; a first foreline bifurcation disposed proximate an outlet of the foreline assembly; two second foreline bifurcations, each disposed between the first foreline bifurcation and a respective pair of the inlets; and the first and second foreline bifurcations dividing the foreline assembly into three sections, a first section extending from the four inlets to the two second foreline bifurcations, a second section extending from the two second foreline bifurcations to the first foreline bifurcation, and a third section extending from the first foreline bifurcation to the outlet of the foreline assembly.

In some examples, the method 1200 further comprises processing a substrate in the QSM using a symmetric RF power path and a symmetric gas flow in each station of the QSM.

Although examples have been described with reference to specific example embodiments or methods, it will be evident that various modifications and changes may be made to these embodiments without departing from the broader scope of the embodiments. Accordingly, the specification and drawings are to be regarded in an illustrative rather than a restrictive sense. The accompanying drawings that form a part hereof, show by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

Such embodiments of the inventive subject matter may be referred to herein, individually and/or collectively, by the term “invention” merely for convenience and without intending to voluntarily limit the scope of this application to any single invention or inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

1. A multi-station process tool comprising:
a plurality of process chambers, each process chamber located at a station of the multi-station process tool; and
a RF power path component associated with each station of the multi-station process tool, the RF power path component positioned and oriented such that, when energized, a symmetric RF power path is created with respect to a symmetry axis of the multi-station process tool.

2. The multi-station process tool of claim 1, wherein the symmetry axis is located at a center of the multi-station process tool.

3. The multi-station process tool of claim 2, wherein the center of the multi-station process tool is defined by an axis of a spindle motor of the multi-station process tool.

4. The multi-station process tool of claim 1, wherein the RF power path component includes an RF component enclosure.

5. The multi-station process tool of claim 1, wherein the multi-station process tool of claim 1 includes a quad station process module (QSM) having a four stations, each station including a process chamber.

6. The multi-station process tool of claim 5, wherein a geometric position and orientation of a first RF power path component in relation to a first station of the four stations of the QSM, is symmetrical with a geometric position and orientation of a second RF power path component in relation to a second station of the four stations of the QSM.

7. The multi-station process tool of claim 6, wherein the geometric position and orientation of a first non-RF component in relation to the first station, is symmetrical with the geometric position and orientation of a second non-RF component in relation to the second station of the QSM.

8. The multi-station process tool of claim 7, wherein an asymmetry of the RF power path component or non-RF component is common to each station of the multi-station process tool.

9. The multi-station process tool of claim 5, further comprising:
a foreline assembly including four inlets each connectable to a chamber port of a station of the QSM;
an outlet connectable directly or indirectly to a vacuum source;
a first foreline bifurcation disposed proximate an outlet of the foreline assembly;
two second foreline bifurcations, each disposed between the first foreline bifurcation and a respective pair of the four inlets; and
the first and second foreline bifurcations dividing the foreline assembly into three sections, a first section extending from the four inlets to the two second foreline bifurcations, a second section extending from the two second foreline bifurcations to the first foreline bifurcation, and a third section extending from the first foreline bifurcation to the outlet of the foreline assembly.

10. The multi-station process tool of claim 9, wherein a respective diameter of a foreline in each section:
increases stepwise at a respective bifurcation in a direction of gas flow from at least one of the four inlets to the outlet of the foreline assembly; and
is constant within a respective section of the foreline assembly.

11. The multi-station process tool of claim 10, wherein a diameter of a foreline in the first section is in a range 38.1 mm (approximately 1.5 inches) to 63.5 mm (approximately 2.5 inches), a diameter of a foreline in the second section is in the range 63.5 mm (approximately 2.5 inches) to 88.9 mm (approximately 3.5 inches), and a diameter of a foreline in the third section is in the range 88.9 mm (approximately 3.5 inches) to 114.3 mm (approximately 4.5 inches).

12. The multi-station process tool of claim 11, wherein the diameter of the foreline in the first section is 50.8 mm (approximately 2 inches), the diameter of the foreline in the second section is 76.2 mm (approximately 3 inches), and the diameter of the foreline in the third section is 101.6 mm (approximately 4 inches).

13. The multi-station process tool of claim 12, further comprising a T-piece connector provided at each of the two second foreline bifurcations.

14. The multi-station process tool of claim 13, wherein the T-piece connector includes outwardly converging conical sections that transition the diameter of the foreline in the first section to the diameter of a foreline in the second section.

15. The multi-station process tool of claim 14, wherein a separation distance between the T-piece connector and an underside of the QSM is configured to accommodate an RF power path component between the T-piece connector and underside of the QSM.

16. A method of providing a symmetric RF power path at a multi-station process tool, the method comprising:
providing a multi-station process tool including a plurality of process chambers, each process chamber located at a station of the multi-station process tool; and
installing a RF power path component in association with each station of the multi-station process tool, the RF power path component being positioned and oriented such that, when energized, a symmetric RF power path is created with respect to a symmetry axis of the multi-station process tool.

17. The method of claim 16, wherein the symmetry axis is located at a center of the multi-station process tool.

18. The method of claim 17, wherein the center of the multi-station process tool is defined by an axis of a spindle motor of the multi-station process tool.

19. The method of claim 16, wherein the RF power path component includes an RF component enclosure.

20. The method of claim 16, wherein the multi-station process tool includes a quad station process module (QSM).

21. The method of claim 20, further comprising configuring the QSM for a symmetric gas flow, the configuring of the QSM comprising, at least:
fitting a foreline assembly to the QSM, the foreline assembly including:
four inlets each connectable to a chamber port of a station of the QSM;
an outlet connectable directly or indirectly to a vacuum source;
a first foreline bifurcation disposed proximate an outlet of the foreline assembly;
two second foreline bifurcations, each disposed between the first foreline bifurcation and a respective pair of the four inlets; and
the first and second foreline bifurcations dividing the foreline assembly into three sections, a first section extending from the four inlets to the two second foreline bifurcations, a second section extending from the two second foreline bifurcations to the first foreline bifurcation, and a third section extending from the first foreline bifurcation to the outlet of the foreline assembly.

22. The method of claim 21, further comprising processing a substrate in the QSM using the symmetric RF power path and a symmetric gas flow in each station of the QSM.
